(19) United States
(12) Patent Application Publication
(10) Pub. No.: US 2002/0079948 A1
(43) Pub. Date: Jun. 27, 2002

(54) Bootstrap circuit in DC/DC static converters

(75) Inventors: Ugo Moriconi, Dalmine (BG) (IT); Claudio Adragna, Monza (MI) (IT)

Correspondence Address: FLEIT, KAIN, GIBBONS,, GUTMAN & BONGINI, P.L., ONE BOCA COMMERCE CENTER, 551 NORTHWEST 77TH STREET, SUITE 111, BOCA RATON, FL, 33487, US

(73) Assignee: STMicroelectronics S.r.I., Agrate Brianza (IT)

(21) Appl. No.: 09/912,073

(22) Filed: Jul. 24, 2001

(30) Foreign Application Priority Data
Jul. 25, 2000 (IT) MI2000A001691

(51) Int. Cl. H03K 17/16

(52) U.S. Cl. 327/390

(57) ABSTRACT

The present invention concerns a bootstrap circuit in DC/DC static converters comprising first current generator means controlled to close in function of a first signal and a recharge circuit of a capacitor. The bootstrap circuit has the characteristic of comprising second current generator means controlled to close with a second signal synchronous with the first signal, the second signal has times and modalities such to send to the capacitor recharge currents such to compensate the discharge of the capacitor itself.

### BACKGROUND OF THE INVENTION

1. Field of the Invention

The present invention refers to a bootstrap circuit in DC/DC static converters, particularly in DC/DC static converters in step-down configuration comprising such bootstrap circuit. The present invention finds particular application in static converters for discrete element circuits.

2. Description of Related Art

DC/DC static converters are widely used in power supplies, actuator systems, displays, signal processing systems etc. and are based on well-known technologies in which a magnetic means, such as a transformer or an inductance, is driven by at least one power switch. Said switches are controlled by a Pulse Width Modulation (PWM) system commutating at a certain frequency set by a system timing signal.

In the field of static converters there are various typologies, such as step-down converters, also known as “buck” converters in which the regulated output voltage is less than the input voltage, step-up converters, also known as “boost” converters in which the regulated output voltage is greater than the input voltage and the converters called “buckboost” in which the regulated output voltage has an inverse sign compared to the input voltage .

In the configuration of the step-down converters, illustrated in FIG. 1, the power switch is represented by an N-channel DMOS transistor in high-side configuration, that is a configuration in which the source terminal is floating and the magnetic means is represented by an inductance L. The source voltage of said DMOS can vary, therefore, between Vin, that is the input voltage of the converter when the DMOS is on and forces current in said inductance L, and -Vd, which is the voltage drop on a recirculation diode when the DMOS is off and the current stored in L flows through said diode. A graph is shown in FIG. 3 representing the circuit of FIG. 1 when the charge connected to it is at the maximum value.

As is well known to a technician in the sector, in order that an N-channel DMOS transistor is well on, that is its channel resistance Rds(ON) is minimized, it is necessary for the voltage difference between the gate terminal and the source terminal of said DMOS to be greater than about 10V. Nevertheless when the DMOS is well on, that is when it operates in deep saturation region, the voltage of the source terminal is about equal to the input voltage, apart from the voltage drop due to the resistance of the DMOS itself. This implies the necessity to have a voltage available which exceeds the input voltage that is wanted to make the DMOS work in deep saturation region. A widely diffused technique to obtain this boosting is the so-called bootstrap technique.

Nevertheless, also in circuit configurations comprising bootstrap means, such as capacitors, inductors and recirculation diodes, there is the disadvantage that the DMOS transistor is driven efficiently and its Rds(ON) is minimum while said bootstrap means guarantee a sufficiently higher voltage than the input voltage.

The limit of the above mentioned bootstrap circuits is that the DMOS cannot be kept on for an indefinitely long time and above all a minimum time has to be guaranteed during which the magnetic means, that is the inductor, degausses. In this period of time the potential of the source terminal must therefore be sufficiently near to zero so that the capacitor recharges.

The need to recharge the capacitor is a pressing problem from the technological point of view when the DC/DC converter functions with charges of modest value because one of the following disadvantages can occur:

a) having a charge of modest value the DMOS “on” time is very short and also the recirculation diode recharge time is short as is shown in FIG. 4. This means that if the charge is sufficiently small the recirculation time of the diode can become so short that it does not enable the capacitor to recharge.

b) the DMOS must be on for a minimum time in function of the delays of the control circuit. When the charge is very low and requires the DMOS to be on for a shorter time than the minimum time, not being able to satisfy such condition, in the short time there is an excess of energy carried on the charge with the consequent slight increase of the output voltage. The control loop in feedback reacts and several commutation cycles are skipped so as to bring the output voltage to the regulation value and re-establish the correct energy balance. In this case, therefore, the time available for recharging the bootstrap capacitor diminishes even further.

c) if the input and output voltages are relatively high (both exceeding around ten Volts) and near each other the voltage forced in the inductor during the time in which the DMOS is on can be so small that the demagnetization of the inductor comes about at the expense of the energy of the capacitance of the source terminal. When this occurs the voltage of the source terminal remains several Volts above zero and the recirculation diode is not switched on, as described in FIG. 5.

d) during the DC/DC converter turning off phase if the output voltage is relatively high (exceeding around ten Volts) the input voltage will diminish very slowly and when it approaches the output voltage it falls back into condition (c). The output voltage does not go to zero monotonically but oscillating.

The result of the previously described phenomena is that the capacitor progressively discharges and as soon as its voltage goes below the threshold voltage of the DMOS transistor, said transistor cannot be switched on again and the converter will be blocked. According to the value of the input and output voltage and of the values of the components constituting the converter, intermittent functioning or a definitive block of the same converter will be obtained.

The U.S. Pat. No. 5,627,460 tells how to use the technique of the so-called “synchronized diode” applied to a DC/DC converter step-down in which the recirculation diode is replaced by an N-channel DMOS in low-side configuration that results being driven in push-pull in respect of the main DMOS. Such a solution is not applicable to the standard typology of the circuits because the latter provides for only one recirculation diode and not two diodes synchronized in push-pull.

The International Rectifier in one of its applicative notes (DT94-1A “Keeping the bootstrap capacitor charged in buck converts”) relating to its device IR2125, suggests to apply a resistor and a Zener diode. This technique is effective when the input voltage is quite higher than the output voltage and therefore not applicable in case (c). In addition if the input voltage has a wide variation interval, to be able to guarantee sufficient current to the minimum input voltage a relatively low resistive value is necessary which leads, when the input voltage is high, to high power dissipation in the resistance and in the Zener.

Other known solutions resort to magnetic means but have the disadvantage that when the charge of the converter has a modest value the magnetic energy is also very low, comparable to or lower than that dissipated by the effect of the not-ideal coupling between the windings with consequent efficiency losses.

### SUMMARY OF THE INVENTION

In view of the state of the technique described, the object of the present invention is to realize a circuit suitable for avoiding the discharging of the bootstrap capacitor so as to permit more effective driving of the DMOS in high-side configuration.

In accordance with the present invention, said object is reached by means of a bootstrap circuit in DC/DC static converters comprising first current generating means controlled to close in function of a first signal and a recharge circuit of a capacitor, characterized in that it comprises second current generating means controlled to close with a second signal synchronous with said first signal, said second signal having times and modalities such to send to said capacitor recharge currents such as to compensate the discharge of said capacitor.

Thanks to the present invention it is possible to realize a circuit capable of eliminating the problems connected to the bootstrap technique.

In addition it is possible to realize a circuit that permits the turning on of a DMOS high-side for an undetermined time.

The present invention finds application also in other typologies of static converters such as the “buck-boost”, the “flyback”, the double switch “forward”, the half bridge and the full bridge, that is circuits used for the control of motors.

### BRIEF DESCRIPTION OF THE DRAWINGS

The characteristics and the advantages of the present invention will appear evident from the following detailed description of an embodiment thereof, illustrated as nonlimiting example in the enclosed drawings, in which:

FIG. 1 shows a configuration of DC/DC static converter in buck configuration with power switch in high-side configuration according to the known technique;

FIG. 2 shows schematically the bootstrap technique applied to a DMOS high-side of a DC/DC static converter in buck configuration, according to the known technique;

FIG. 3 shows a typical waveform of the circuit in FIG. 1 in the case of maximum charge;

FIG. 4 shows a typical waveform of the circuit in FIG. 1 in the case of light charge;

FIG. 5 shows a typical waveform of the circuit in FIG. 1 in the case of extremely low value;

FIG. 6 shows the base drawing of the circuit according to the present invention;

FIG. 7 shows a time diagram referred to the circuit in FIG. 6;

FIG. 8 shows an applicative example of the present invention to a device marketed by the Applicant; and

FIG. 9 shows another applicative example of the present invention to the same device marketed by the Applicant.

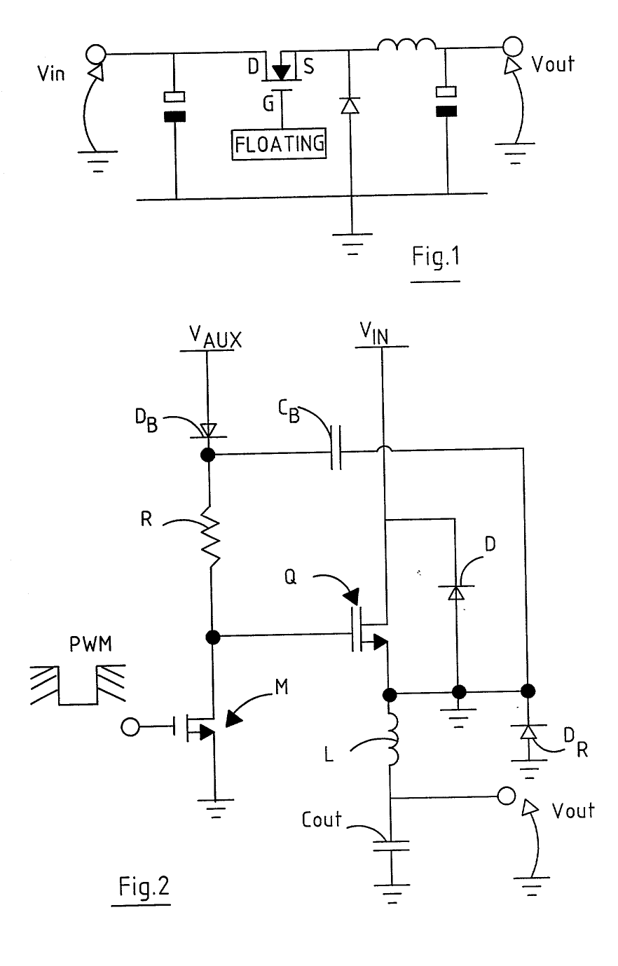

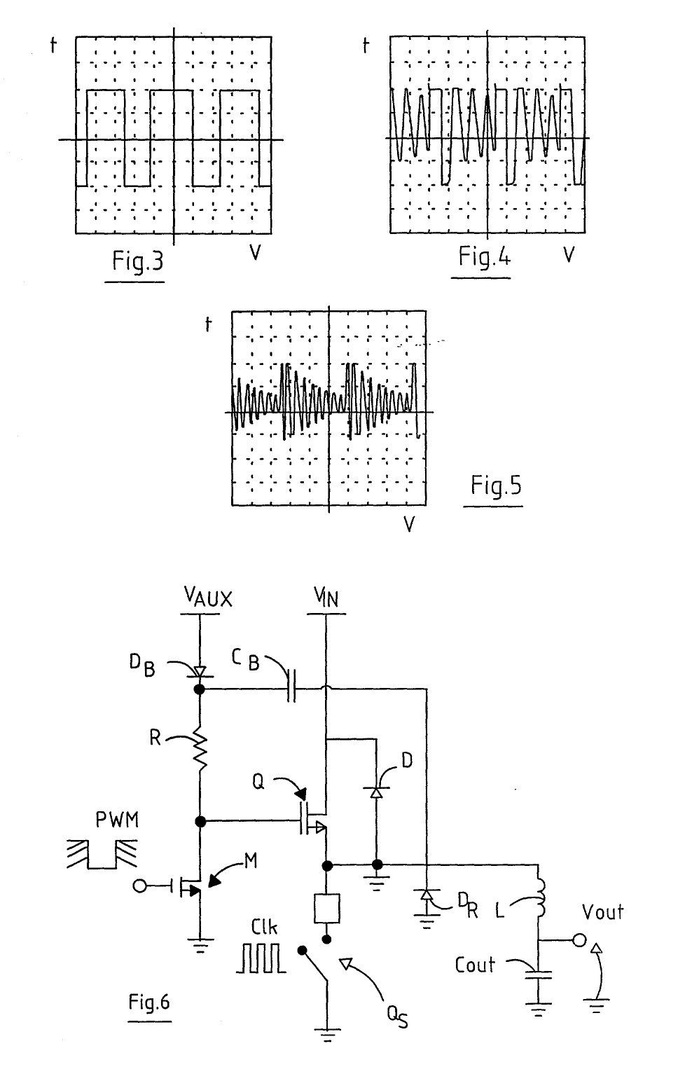

### DETAILED DESCRIPTION OF PREFERRED EMBODIMENTS

In FIG. 2 a circuit is shown schematically using the bootstrap technique applied to a DMOS high-side of a DC/DC static converter in configuration buck, according to the known technique.

According to what is illustrated in said Figure a DMOS type transistor Q can be noted having an internal diode D and its own source terminal connected with an inductance L in turn connected with an output capacitor Cout, grounded, and in addition said source terminal is also connected with a cathode terminal of a recirculation diode Dr, said diode Dr, in addition, has its anode terminal connected to ground. The output terminal of the circuit, called Vout, is placed at the leads of the capacitor Cout. The drain terminal of the DMOS Q is connected to a first supply line Vin, while the gate terminal of the DMOS Q has in parallel respectively, the series of a resistance R and of a diode D_{B}, with a M signal transistor of the MOSFET type. The latter has its source terminal connected to ground and the gate terminal acts as input for a PWM type signal, generated with known techniques, such as the combination of a tooth-saw generator and a modulating signal confronted by a comparator with double trigger threshold. The drain terminal of M represents the connection with the DMOS Q.

The resistance R and diode D_{B} series are arranged so that said R is the connection with the gate terminal of said DMOS Q, and that said diode D_{B} has the anode connected to a second supply line Vaux, with Vaux>Vin, and that the cathode connected with said R is also connected with a plate of a capacitor C_{B}.

Said C_{B} has the other plate connected with the source terminal of said DMOS Q. C_{B} is the element suitable for storing the charge, which in combination with said second supply, permits the circuit shown in the Figure to keep the DMOS Q well on and therefore to minimize the resistance Rds(ON).

In fact when there is a high signal at the gate terminal of M, with R suitably sized, we are in a situation in which M is on and Q is off and therefore the voltage at the leads of the capacitor C_{B} is: V_{CB}=Vaux−VD_{B} with V_{DB} being the voltage drop at the leads of the diode D_{B} in condition of direct polarization.

Vice versa when there is a low signal at the gate terminal of M, the voltage on the gate terminal of the DMOS Q starts to increase because the diode D_{B} charges the intrinsic capacitances C_{GD} and C_{GS} of the DMOS Q. In addition V_{CB} does not vary instantaneously because the current that flows in the mesh is not infinite and finally the diode D_{B} goes off as point A is increased in voltage in the same quantity as the source terminal of the DMOS Q. We are therefore in a situation in which C_{B} is isolated (current does not flow in the mesh) and therefore said C_{B} acts like a battery giving origin to a difference in potential between gate and source of Q equal to: V_{GS}=V_{CB}. The voltage at the gate terminal of Q rises to a level equal to: V_{G}=V_{CB} +Vin=Vin+Vaux−V_{DB}.

The base drawing of the circuit according to the present invention is shown in FIG. 6. As can be inferred from said Figure in addition to the devices already described in FIG. 2 there is also a switch Q_{S} and a resistive means R_{S}. The closing and opening of the switch Q_{S} is controlled by a time signal at fixed frequency, for example a clock signal.

The switch Q_{S} is preferably a MOSFET transistor or a bipolar transistor. In this particular case using a transistor for realizing the switch, said transistor must have the source terminal connected to ground and the drain terminal connected to the floating end of the capacitor C_{B} by means of said resistive means R_{S}.

The clock signal suitable for controlling Q_{S} is synchronized, by means of known techniques, with the signal generated by the PWM circuit, that is with the signal placed at the gate terminal of the transistor M. In particular the synchronism lies in the condition that when the PWM signal is high the clock signal must be high.

Therefore when the pulse to the gate terminal of M is high, Q is off and the signal suitable for controlling Q_{S} is high, that means that Q_{S} is on. The turning on of Q_{S} carries out an operation commonly known as “refresh” of the capacitor C_{B} that is the charge present in said capacitor is regenerated. In this manner the charge lost by the capacitor because of the parasitisms and of the leakage current that afflict the capacitor itself is reintegrated.

The resistive means R_{S} is a limitation resistance and serves both to limit the charge current of C_{B} and to limit the current peak due to the fact that, even though for a very short time, there is contemporary conduction of Q and Q_{S}, that is, when there is a crossconduction of the two transistors.

It is to be noted that should the switch be realized with a MOSFET type transistor the problem of crossconduction would be considerably reduced.

The value of said resistance R_{S} is not critical, nevertheless it cannot be too low, as there would be current peaks, but not even too high, as the discharge constant of C_{B} would be too long. The Applicant has found that the values comprised in an interval from 10 a 100 Ohm are preferable in function of the values of the input voltages Vin and the output voltages Vout.

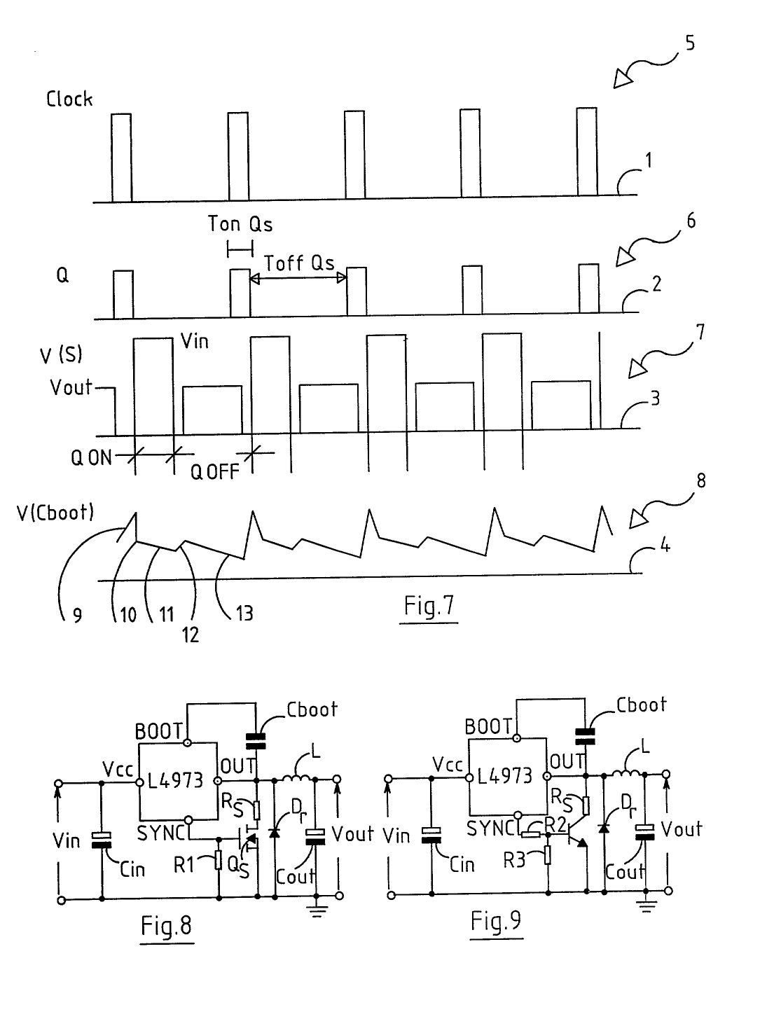

In reference to the graphs given in FIG. 7 a plurality of X-axes 1-4 indicating the time can be noted and in particular graph 5 shows the course of the clock pulse suitable for controlling Q_{S}; graph 6 shows the time duration both of the turning on, TonQ_{S}, and of the turning off, ToffQ_{S}, of the switch Q_{S}; graph 7 shows the course of the voltage at the leads of the inductance L that is of the output voltage Vout and the time duration both of the turning on, TonQ, and of the turning off, ToffQ, of the DMOS transistor Q; finally graph 8 shows the course of the voltage at the leads of the capacitor C_{B}.

In particular from graph 8 it can be inferred that the capacitance C_{B} undergoes a charge phase 9 during TonQ_{S}, that brings the capacitor to the maximum storable value, a steep but brief discharge phase 10 due to a capacitive partition between the C_{B} and the equivalent capacitor of the gate terminal of Q, a further discharge phase 11 during the turning on of Q because of an internal consumption of the circuit, a charge phase 12 thanks to the inventive circuit, and finally a discharge phase 13 during the turning off of Q, because of an internal consumption of the circuit.

As can be inferred from graph 8 the charge/discharge phases of C_{B} are periodically repeated in time, because the charge/discharge operations are controlled by a signal at fixed frequency.

An example of the application of the present invention is shown in FIG. 8 in which a device produced and marketed by the Applicant known by the number L4973, (ref “Application Note 938, Designing With L4973, 3.5A High Efficiency DC-DC Converter, STMicroelectronics”) can be noted and of which 4 output pins are represented and in particular the pin Vcc, the pin BOOT, the pin OUT and the pin SYNC. In addition the presence of a resistance R1 can be noted, preferably with the value of 4,7 KOhm so as to control the DMOS Q_{S} in voltage, an input capacitor Cin, and the recirculation diode, Dr.

The pin SYNC makes the clock pulses inside the integrated circuit available and generally it is used to synchronize another device if present. In this embodiment the synchronism pulses represent the fixed frequency signal of the circuit proposed in FIG. 6 and therefore said synchronism signal gives the command to the MOS Q_{S} to regenerate the charge of the capacitor C_{B}.

The presence of R_{S} serves to limit the charge current of C_{B} both for reducing the discharge peak because of the crossconduction of the DMOS Q inside the integrated L4973 and for the MOS Q_{S}.

A further application example of the present invention is shown in FIG. 9 in which the device L4973 produced and marketed by the Applicant can be noted, having a bipolar transistor Q_{S} with a limitation resistance R_{S} and two resistances R2 and R3 connected on the pin SYNC in order to drive said bipolar Q_{S} in current.

The resistances R2 and R3 preferable have a value of 10 Kohm each one.

The functioning of the circuit illustrated in said Figure is similar to that of FIG. 8 with the specification that said resistance R_{S}, as well as limiting the charge current of C_{B}, also serves to limit the current peak due to the fact that, even though for a very brief period, there is a contemporary conduction of the DMOS Q inside the integrated L4973 and the bipolar transistor Q_{S}.

While there has been illustrated and described what are presently considered to be the preferred embodiments of the present invention, it will be understood by those skilled in the art that various other modifications may be made, and equivalents may be substituted, without departing from the true scope of the present invention. Additionally, many modifications may be made to adapt a particular situation to the teachings of the present invention without departing from the central inventive concept described herein. Furthermore, an embodiment of the present invention may not include all of the features described above. Therefore, it is intended that the present invention not be limited to the particular embodiments disclosed, but that the invention include all embodiments falling within the scope of the appended claims.

What is claimed is:

1. Bootstrap circuit in DC/DC static converters comprising first current generator means controlled to close in function of a first signal and a recharge circuit of a capacitor, second current generator means controlled to close with a second signal synchronous with said first signal, said second signal having times and modalities such to send to said recharge circuit of said capacitor recharge currents such to compensate the discharge of said capacitor.

2. Bootstrap circuit in DC/DC static converters according to claim 1, wherein said second current generator means are a series of a first resistance and a transistor.

3. Bootstrap circuit in DC/DC static converters according to claim 1, wherein said second signal is a time signal having a fixed frequency.

4. Bootstrap circuit in DC/DC static converters according to claim 1, wherein said first signal is a pulse width modulation signal.

5. Bootstrap circuit in DC/DC static converters according to claim 2, wherein said transistor is an N-channel MOSFET transistor.

6. Bootstrap circuit in DC/DC static converters according to claim 5, wherein said transistor MOSFET has the source terminal connected to ground, and the drain terminal connected to the floating end of said capacitor by means of said first resistance.

7. Bootstrap circuit in DC/DC static converters according to claim 2, wherein said transistor is a pnp type bipolar transistor.

8. Bootstrap circuit in DC/DC static converters according to claim 7, wherein said bipolar transistor has the source terminal connected to ground, and the drain terminal connected to the floating end of said capacitor by means of said first resistance.

9. Bootstrap circuit in DC/DC static converters according to claim 2, wherein said first resistance has a value within an interval of between 10 and 100 Ohm.

10. Bootstrap circuit in DC/DC static converters according to claim 1, wherein said first current generator means includes current generators, a MOSFET signal transistor and a DMOS power transistor.

11. Bootstrap circuit in DC/DC static converters according to claim 1, wherein said recharge circuit includes a second supply line to which the series of a second resistance and a diode is connected, so that said diode has its anode terminal connected to said second supply line, the cathode terminal is connected with said second resistance and that said cathode terminal is also connected with the fixed terminal of said capacitor and that said second resistance is the connection with the gate terminal of said DMOS, and wherein said recharge circuit also includes a first supply line to which a DMOS transistor is connected by means of its own drain terminal.
